(19) United States
(12) Patent Application Publication
(10) Pub. No.: US 2024/0014242 A1
(43) Pub. Date: Jan. 11, 2024

(54) SPAD-BASED DEVICES WITH TRANSISTOR STACKING

(71) Applicant: SEMICONDUCTOR COMPONENTS INDUSTRIES, LLC, Phoenix, AZ (US)

(72) Inventors: Jan LEDVINA, Tovacov (CZ); Dariusz Piotr PALUBIAK, Passage West (IE)

(73) Assignee: SEMICONDUCTOR COMPONENTS INDUSTRIES, LLC, Phoenix, AZ (US)

(21) Appl. No.: 17/811,149

(22) Filed: Jul. 7, 2022

(51) Int. Cl. H01L 27/146

(52) U.S. Cl. CPC H01L 27/14634

(57) ABSTRACT

An imaging system may include a plurality of SPAD pixels. Each SPAD pixel may have a SPAD on a first die and reset, quench, and readout circuitry on a second die. The circuitry for a SPAD pixel on the second die may include stacked-transistor structures configured to operate in a high voltage domain and may include readout circuitry configured to operate in a low voltage domain. The stacked-transistor structures may include p-type transistors formed at a same n-type substrate well and sharing a same bulk connection. The stacked-transistor structures may also include n-type transistors formed at a same p-type substrate well and sharing a same bulk connection.

### BACKGROUND

This relates generally to imaging systems, and more specifically, to imaging systems with single-photon avalanche diodes (SPADs).

A SPAD is a type of P-N junction diode biased above a breakdown voltage by an excess voltage. In this state, the SPAD can be sensitive to a single impinging photon. To enhance SPAD performance (e.g., avalanche initiation probability, timing jitter, etc.), it may be desirable to provide an excess voltage at a relatively high (voltage) level. This characteristic is especially pronounced for SPADs forming a LIDAR (light detection and ranging) imaging system operating at NIR (near infrared) wavelengths, where avalanche initiation probability is more critical.

In some implementations of the SPAD-based imaging system, it can be difficult to provide the excess voltage at a sufficiently high voltage level. As an example, to enhance the functionality and performance of the imaging system, a SPAD-based imaging system can be implemented using a stacked-die device with a sensor die and a readout die mounted to each other. In this example, the readout die can be formed from circuitry operating at low voltages, which are unable to supply the desired high level of the excess voltage.

It is within this context that the embodiments described herein arise.

### BRIEF DESCRIPTION OF THE DRAWINGS

FIG. 1 is a functional block diagram of an illustrative SPAD-based imaging system in accordance with some embodiments.

FIG. 2 is a diagram of an illustrative stacked-die device in accordance with some embodiments.

FIG. 3 is a schematic diagram of an illustrative SPAD pixel in accordance with some embodiments.

FIG. 4 is a circuit diagram of illustrative stacked transistor circuitry in accordance with some embodiments.

FIGS. 5-10 are circuit diagrams of illustrative elementary circuits formed using a stacked transistor architecture in accordance with some embodiments.

FIG. 11 is an illustrative schematic diagram of an illustrative SPAD pixel formed from elementary circuits with a stacked transistor architecture in accordance with some embodiments.

FIG. 12 is a circuit diagram of an illustrative portion of a SPAD pixel with stacked transistor circuitry in accordance with some embodiments.

FIG. 13 a cross-sectional view of a substrate for implementing an illustrative SPAD pixel portion such as that of FIG. 12 in accordance with some embodiments.

### DETAILED DESCRIPTION

Imaging systems or devices may include single-photon avalanche diodes (SPADs), thereby forming SPAD-based imaging systems or devices (sometimes referred to herein simply as SPAD devices).

Some imaging systems include image sensors that sense light by converting impinging photons into electrons or holes that are integrated (collected) in pixel photodiodes within the sensor array. After completion of an integration cycle, collected charge is converted into a voltage, which is supplied to the output terminals of the sensor. In complementary metal-oxide semiconductor (CMOS) image sensors, the charge to voltage conversion is accomplished directly in the pixels themselves and the analog pixel voltage is transferred to the output terminals through various pixel addressing and scanning schemes. The analog pixel voltage can also be later converted on-chip to a digital equivalent and processed in various ways in the digital domain.

In SPAD devices, on the other hand, the photon detection principle is different. In some illustrative configurations sometimes described herein as an example, SPAD devices may form light detection and ranging (LIDAR) devices or imaging systems. A LIDAR device may include a light source that emits light toward a target object/scene. The light sensing diode (SPAD) in the LIDAR device may be biased above its breakdown point and when an incident photon from the light source (e.g., light that has reflected off of the target object/scene) generates an electron or hole, this carrier initiates an avalanche breakdown with additional carriers being generated. The avalanche multiplication may produce a current signal that can be easily detected by readout circuitry associated with the SPAD. The avalanche process needs to be stopped (quenched) by lowering the diode bias below its breakdown point. In LIDAR devices, the SPAD pixels may be used to measure photon time-of-flight (ToF) from a synchronized light source to a scene object point and back to the sensor, which can be used to obtain a 3-dimensional image of the scene (as an example).

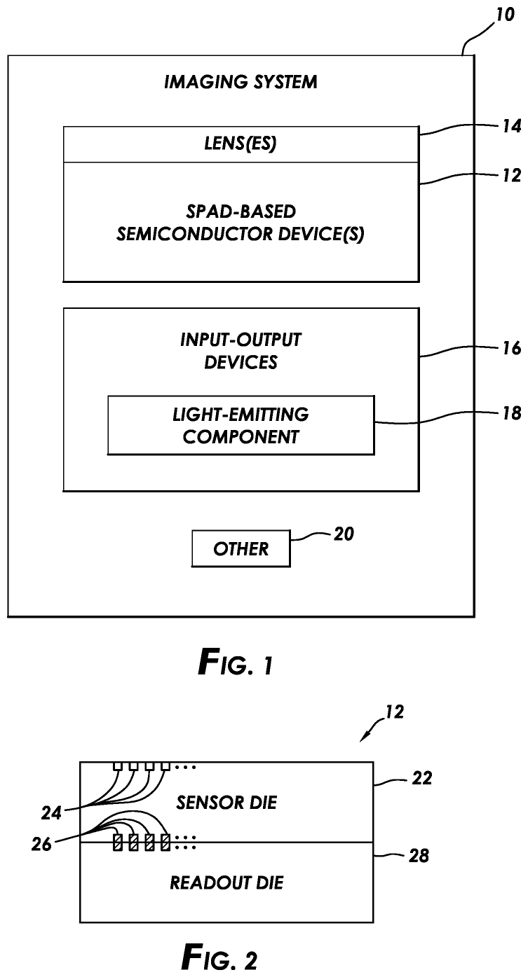

FIG. 1 is a functional block diagram of an illustrative imaging system such as imaging system 10. Imaging system 10 of FIG. 1 may be a vehicle safety system (e.g., an active braking system or other vehicle safety system), a surveillance system, a medical imaging system, a general machine vision system, or any other desired type of system.

System 10 may include or implement a LIDAR-based device (sometimes referred to as a LIDAR module) having SPAD device(s). The LIDAR module may use the SPAD device(s) to capture images of a scene and measure distances to obstacles (also referred to as targets) in the scene. As an example, in a vehicle safety system, information from the LIDAR module may be used by the vehicle safety system to determine environmental conditions surrounding the vehicle. As examples, vehicle safety systems may include systems such as a parking assistance system, an automatic or semi-automatic cruise control system, an auto-braking system, a collision avoidance system, a lane keeping system (sometimes referred to as a lane-drift avoidance system), a pedestrian detection system, etc. In at least some instances, the LIDAR module may form part of a semi-autonomous or autonomous self-driving vehicle.

As shown in FIG. 1, imaging system 10 may include one or more SPAD-based (semiconductor) devices 12. One or more lenses 14 may cover each SPAD-based device 12. During operation, lenses 14 (sometimes referred to as optics) may focus light onto corresponding SPAD-based semiconductor devices 12. SPAD-based devices 12 may each include (an array of) SPAD pixels that convert the light into digital data. The SPAD-based device 12 may have any number of SPAD pixels (e.g., hundreds, thousands, millions, or more). In some SPAD-based devices, each SPAD pixel may be covered by a respective color filter element and/or microlens.

SPAD-based device 12 may include control circuitry. The control circuitry for SPAD-based device 12 may be formed either on-chip (e.g., on the same semiconductor substrate as the SPAD-based device 12) or off-chip (e.g., on a different semiconductor substrate as the SPAD-based device 12). The control circuitry may control operation of SPAD-based device 12. For example, the control circuitry may operate active quenching circuitry or other adjustable (transistor) circuitry within each SPAD pixel, may control one or more bias voltages provided to each SPAD pixel, may control/monitor the readout circuitry associated with each SPAD pixel, etc.

The SPAD-based semiconductor device 12 may optionally include additional circuitry such as logic gates, digital counters, time-to-digital converters, bias circuitry (e.g., source follower load circuits), sample and hold circuitry, correlated double sampling (CDS) circuitry, amplifier circuitry, analog-to-digital (ADC) converter circuitry, data output circuitry, memory (e.g., buffer circuitry), address circuitry, etc. Any of the aforementioned circuits may form part of the control circuitry or, when provided on a per-pixel basis, may form part of the SPAD pixel.

If desired, image data output from SPAD-based device 12 may be provided to downstream image processing circuitry. The image processing circuitry may be used to perform image processing functions such as automatic focusing functions, depth sensing, data formatting, adjusting white balance and exposure, implementing video image stabilization, face detection, etc. For example, during automatic focusing operations, the image processing circuitry may process data gathered by the SPAD pixels to determine the magnitude and direction of lens movement needed to bring an object of interest into focus. The image processing circuitry may process data gathered by the SPAD pixels to determine a depth map of the scene (as another example). In some cases, some or all of the control circuitry for SPAD device 12 may be formed integrally with the image processing circuitry (e.g., on the same die or package).

Imaging system 10 may provide a user with numerous high-level functions. For example, a user may be provided with the ability to run user applications on system 10. To implement these functions, imaging system 10 may include input-output devices 16 such as keypads, buttons, input-output ports, joysticks, and displays. If desired, other functional modules and/or additional storage and processing circuitry (e.g., other components 20) such as volatile and nonvolatile memory (e.g., random-access memory, flash memory, hard drives, solid state drives, etc.), microprocessors, microcontrollers, digital signal processors, application specific integrated circuits, and/or other processing circuits for other (non-imaging) functional modules may also be included in imaging system 10.

Input-output devices 16 may include output devices that work in combination with SPAD-based devices 12. For example, one or more light-emitting components 18 may be included in imaging system 10 to emit light (e.g., infrared light or light of any other desired type). Light-emitting component 18 may be a laser, light-emitting diode, or any other desired type of light-emitting component. SPAD-based device 12 may measure the reflection of the light off of an object to measure distance to the object in a LIDAR scheme (e.g., in scenarios where imaging system 10 implements or includes a LIDAR module). The control circuitry that is used to control operation of SPAD-based device 12 may optionally also be used to control operation of light-emitting component 18 for a coordinated sensing scheme.

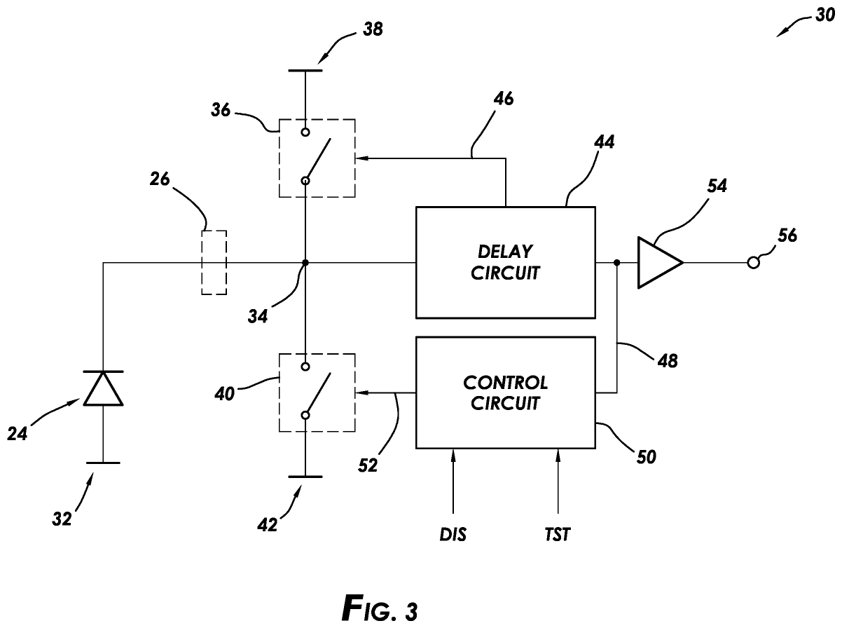

In order to enhance the functionality of SPAD device 12, SPAD device 12 may be implemented as a stacked-die device. FIG. 2 is a diagram of an illustrative stacked-die device for implementing SPAD device 12. As shown in FIG. 2, SPAD device 12 may include a first integrated circuit die such as sensor (circuitry) die 22 and a second integrated circuit die such as readout (circuitry) die 28. Because different types of functional circuitry are formed on the two respective dies, each die can be formed in a manner optimized for its dedicated function (e.g., formed using processes, technologies, layouts, designs, etc., optimized for its function).

As an example, sensor die 22 may include an array of SPADs 24 each forming a portion of the corresponding SPAD pixel. In some illustrative arrangements described herein as an illustrative example, sensor die 22 may be formed such that SPADs 24 are configured (e.g., optimized) to be sensitive to light of NIR wavelengths and/or light of other wavelengths of interest (e.g., corresponding to the light emitted by component 18 in FIG. 1). If desired, sensor die 22 may be a backside illuminated (BSI) sensor die (e.g., dielectric and metal interconnect layers for sensor die 22 may be formed on the bottom side of die 22 in the view of FIG. 2).

Readout die 28 may include an array of readout circuits each forming a remain portion of the corresponding SPAD pixel, may include the control circuitry of SPAD device 12 as described in connection with FIG. 1, and/or may include other circuitry that support the operation of SPAD device 12. In some illustrative arrangements described herein as an illustrative example, readout die 28 may include SPAD readout circuits (e.g., the readout path and intervening elements along the readout path through which detection signals responsive to impinging photons are passed), SPAD quenching circuits (e.g., for actively or passively quenching one or more corresponding SPADs), SPAD reset circuits (e.g., for resetting one or more corresponding SPADs), control circuitry configured to control the readout, quenching, and reset circuits, power supply and management circuitry, and other suitable circuitry. As an example, readout die 28 may be implemented as a low-voltage circuitry die formed from a CMOS (complementary metal-oxide-semiconductor) process and optimized for digital functionality.

In other words, as described above, each SPAD pixel may have a first portion (e.g., SPAD 24) formed in die 22 and may have a second portion (e.g., readout circuits, quenching circuits, reset circuits, control circuitry, power supply circuitry, etc.) formed in die 24. The two portions may be connected using die interconnect structures such as interconnect structures 26. In some illustrative arrangements described herein as an example, interconnect structures 26 may be implemented as hybrid bonds. Each interconnect structure 26 (having portions in both dies) may be provided at the pixel level such that each pixel may have a corresponding interconnect structure 26. If desired, in shared pixel schemes (e.g., a readout circuit may be shared by multiple SPADs), an interconnect structure 26 may be shared by multiple pixels (e.g., provide connection to multiple SPADs).

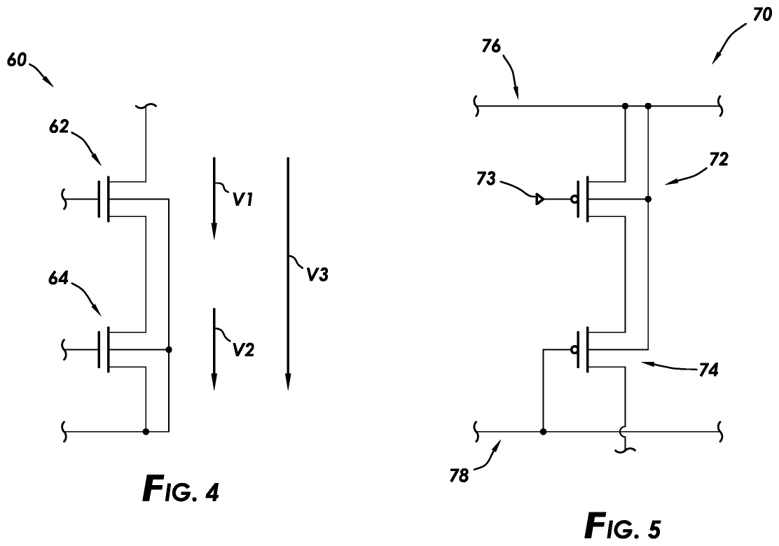

FIG. 3 is a schematic diagram of an illustrative SPAD pixel such as SPAD pixel 30, a plurality of which may be formed in SPAD device 12 as shown in FIGS. 1 and 2. As shown in FIG. 3, SPAD pixel 30 includes a SPAD 24 having an anode terminal connected to voltage supply terminal 32 and a cathode terminal 34 connected to voltage supply terminal 38 via switch 36 (e.g., transistor 36), when switch 36 is closed or activated (e.g., in a conductive state). To prepare for a detection operation using SPAD pixel 30, supply voltage terminals 32 and 38 may be used to bias SPAD 24 to a voltage (e.g., across SPAD 24) that is higher than the breakdown voltage of SPAD 24. The breakdown voltage is the largest reverse bias voltage that can be applied to SPAD 24 without causing an exponential increase in the leakage current in SPAD 24. When SPAD 24 is reverse biased above the breakdown voltage in this manner, absorption of a single photon can trigger a short-duration but relatively large avalanche current through impact ionization, thereby providing single-photon sensitivity.

A quenching circuit may be used to lower the bias voltage of SPAD 24 below the level of the breakdown voltage. Lowering the bias voltage of SPAD 24 below the breakdown voltage stops the avalanche process and corresponding avalanche current. There are numerous ways to form a quenching circuit. As examples, the quenching circuit may be a passive quenching circuit or an active quenching circuit. A passive quenching circuit may, without external control or monitoring, automatically quench the avalanche current once initiated. As an example, a resistor (e.g., a passive resistive component) coupled between the cathode terminal of the SPAD and a corresponding voltage supply terminal may serve as a passive quenching circuit.

In the example of FIG. 3, pixel 30 includes an active quenching circuit. The active quenching circuit may reduce the time it takes for SPAD 24 to be quenched and reset (e.g., the dead-time). This may allow SPAD 24 to detect incident light at a faster rate than when a passive quenching circuit is used, thereby improving the dynamic range of the SPAD device. As shown in FIG. 3, the (active) quenching circuit of pixel 30 may include switch 40 (e.g., transistor 40) coupling cathode terminal 34 to voltage supply terminal 42 (e.g., supplying a ground voltage V_{SS}). Once closed (e.g., in a conductive state), switch 40 may provide the ground voltage V_{SS} at terminal 42 to cathode terminal 34 of SPAD 24. To control the state of switch 40, the quenching circuit of pixel 30 may also include control circuit 50 that supplies a control signal along path 52 that controls the state of switch 40 (e.g., to switch between open and closed states). While control circuit 50 may control switch 40 (e.g., by asserting and de-asserting the corresponding control signal) in any suitable manner, in the example of FIG. 3, the output signal from delay circuit 44 coupled along the SPAD readout path (e.g., the signal along path 48) may be used to generate control signal 52.

In other words, in this active quenching scheme, the active quenching circuit (e.g., control circuit 50) may modulate the SPAD quench resistance (e.g., switch 40) based on SPAD operation. For example, before a photon is detected, quench resistance is set high (e.g., switch 40 is controlled to be in an open or high resistivity state) and then once a photon is detected (and after a period of delay set by delay circuit 44), the quench resistance is minimized (e.g., switch 40 is controlled to be in a closed or low resistivity state) and the avalanche is quenched to reduce recovery time.

In a similar manner, delay circuit 44 may provide a control signal on path 46 (e.g., based on an introduced delay) to control switch 36 to be in open or closed states at corresponding times. As an example, a suitable time period after the quenching operation (e.g., the assertion of the control signal on path 52 to close switch 40), delay circuit 44 may provide an asserted control signal to close switch 36 to reset SPAD 24 and prepare for detection of a subsequent photon.

In the example of FIG. 3, the readout path of pixel 30 may include delay circuit 44 and driver circuit 54. Delay circuit 44 and driver circuit 54 may pass a detection signal (responsive to a detected impinging photon) from cathode terminal 34 to a pixel output terminal 56. If desired, specific functional circuits such as a variable or constant hold-off timer circuit, a variable or constant reset timer circuit, a reset time-out circuit, etc., may be coupled along the readout path of pixel 30 between terminals 34 and 56 instead of or in addition to delay circuit 44 and/or driver circuit 54. The detection signal exiting pixel from output terminal 56 may be processed by downstream digital processing circuitry.

To provide additional functionalities to SPAD pixel 30, control circuit 50 may receive additional input signals DIS and TST. In particular, input signal DIS may be a disable signal that, when asserted, enables control circuit 50 to use (assert) the control signal on path 52 to maintain switch 40 in a closed or activated state such that SPAD avalanching is prevented, thereby actively disabling pixel 30 from performing sensing operations. Input signal TST may be a test signal that, when asserted, enables control circuit 50 to control switch 40 and/or other pixel elements to respond to a test input, thereby providing testability to pixel 30.

In one suitable arrangement to achieve the reverse biased state of SPAD 24, voltage supply terminal 32 may supply a negative voltage −V_{HV} at or near the breakdown voltage and voltage supply terminal 38 may supply a positive excess voltage V_{EX}. It may be desirable to provide positive excess voltage V_{EX} at a relatively high voltage level (e.g., having a large magnitude). This is because it is not guaranteed that each impinging photon is detected by the SPAD in this reverse biased state. The probability that the SPAD successfully detects the photon is referred to as the photon detection probability (PDP), which takes into account (e.g., is the product of) the quantum efficiency (QE) and the avalanche initiation probability (AIP). Because AIP is mainly determined by the magnitude of positive excess voltage V_{EX}, it is therefore desirable to increase (e.g., maximize) the magnitude of positive excess voltage V_{EX} to improved AIP and therefore PDP. Further, in operating configurations or applications where QE is relatively low (e.g., in NIR sensing applications), providing a relatively high excess voltage V_{EX} becomes even more critical.

However, in arrangements where the SPAD device is formed from a stacked-die configuration such as the stacked-die device forming SPAD device 12 in FIG. 2, the maximum magnitude of positive excess voltage V_{EX} may be determined (e.g., limited) by the specifications of the readout die rather than directly by the sensor die. In particular, in an illustrative stacked-die implementation described herein as an example, a first portion of pixel 30 having SPAD 24 may be formed on sensor die 22, while a second portion of pixel 30 having switch 36, voltage supply terminal 38, and the corresponding power supply (management) circuitry configured to provide voltage supply terminal 38 with voltage V_{EX} may be formed on readout die 28. In the example of FIG. 3, interconnect structure 26 is shown at an illustrative location between SPAD 24 and switch 36 indicative of the boundaries or interfaces between dies 22 and 28.

Accordingly, because readout die 28 may be formed with digital circuitry having low operating voltages (e.g., a digital circuitry supply voltage V_{DD}) to reduce power consumption, readout die 28 may be unable to supply an excess voltage V_{EX} at a sufficiently high level (e.g., above voltage V_{DD}). Even in a dual gate implementation of a die in which a very low voltage (e.g., in a first voltage domain with a maximum supply voltage V_{DD} at 1 V) is supplied to operate the core digital circuitry having thin-oxide transistors and a higher voltage (e.g., in a second voltage domain with a maximum supply voltage V_{DDA} at 2.5V) is supplied to operate analog and/or input-output interface circuitry having thick-oxide transistors, the higher of the two voltages may still be insufficient to supply an excess voltage V_{EX} (e.g., at 5 V, 4 V, 3 V, greater than 2.5 V, etc.) at a sufficiently high level (e.g., above voltage V_{DDA}). To mitigate these issues and in general provide a way to provide excess voltage V_{EX} at a sufficiently high level not directly limited by the supply voltage of digital circuitry (and/or an elevated supply voltage for other analog circuitry) on readout die 28, pixel 30 may employ stacked-transistor structures.

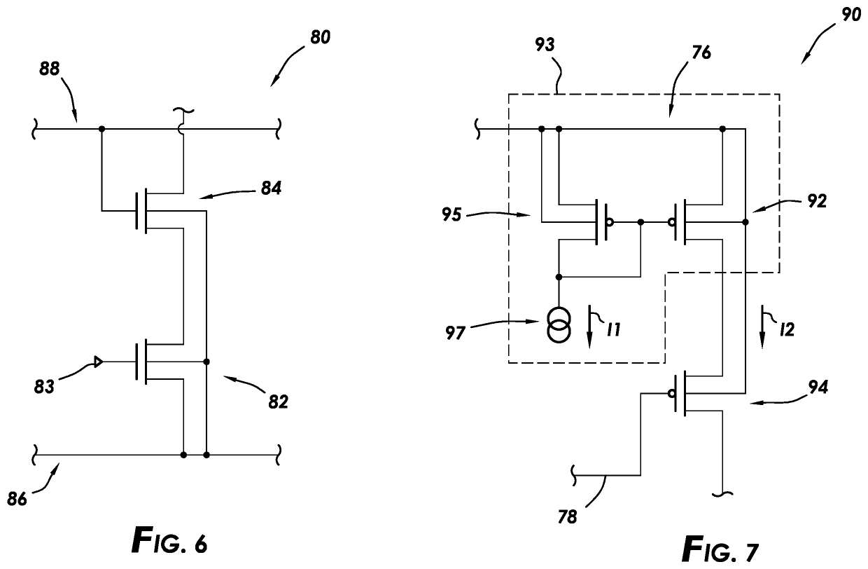

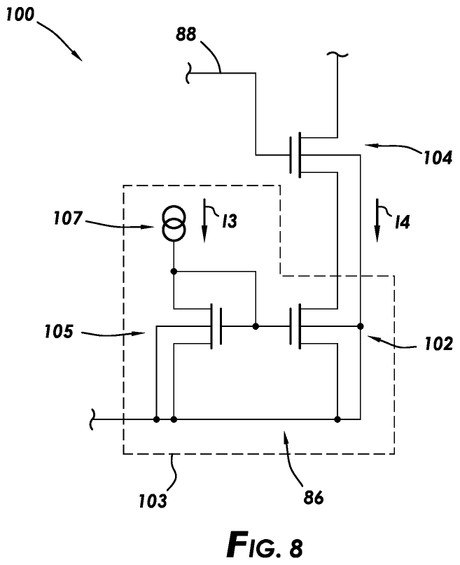

FIG. 4 is a circuit diagram of an illustrative stacked-transistor structure such as stacked-transistor structure 60 (sometimes referred to as stacked-transistor device 60 or stacked-transistor circuit 60). In the example of FIG. 6, stacked-transistor structure 60 may include a first transistor such as n-type transistor 62 coupled in series with a second transistor such as n-type transistor 64. Transistor 62 and 64 may share a bulk or body connection, which receives a common voltage (e.g., a ground voltage V_{SS}). As shown in FIG. 4, the source terminal of transistor 64 may be connected to the same common voltage (e.g., voltage V_{SS}). The drain terminal of transistor 62 may supplied with a desired excess voltage V_{EX} (as an example). By dividing the total voltage drop (e.g., voltage V_{EX}) across the two transistors, transistors 62 and 64 may each operate within the desired voltage swings (e.g., voltages V1 and V2, e.g., each around the normal supply voltage V_{DD}) as specified for the readout die circuitry, while a relatively high cumulative voltage drop V3, which is a sum of voltages V1 and V2 may be realized across the entire stacked-transistor structure 60. As desired, the large cumulative voltage difference V3 may be used supply SPAD 24 (FIG. 3) with a relatively high excess voltage V_{EX}.

Using the stacked-transistor scheme, pixel circuits directly connected to the SPAD may each be formed using this stacked-transistor scheme to cumulatively form a high voltage domain in which the SPAD is operated (e.g., reset, quenched, through which the SPAD detection signal is received, etc.). Depending on the configured of the SPAD pixel, different stacked-transistor devices may be used to form the SPAD pixel. FIGS. 5-10 are circuit diagrams of illustrative elementary functional circuits with stacked transistors, one or more of which may be used in combination with one another to form the SPAD pixel.

FIG. 5 shows an illustrative p-type switch formed from a pair of transistors couples in series. In particular, p-type switch 70 may include p-type (p-channel) transistor 72 coupled in series with p-type transistor 74. Transistors 72 and 74 may share a bulk connection to power (voltage) supply rail or terminal 76 supplying the highest supply voltage level in the pixel (e.g., excess voltage V_{EX} greater than digital supply voltage V_{DD}). Transistor 72 may serve as the main switching transistor (sometimes referred to as the switching device). In other words, a control input 73 received at the gate terminal of transistor 72 may determine the state of transistor 72 and therefore the state of p-type switch 70. Transistor 74 may serve as the protection transistor (sometimes referred to as the protection device). Transistor 74 may receive at its gate terminal a bias voltage from bias voltage supply rail or terminal 78, thereby generating a bias current and corresponding voltage drop across transistor 74. In this manner, transistor 74 is configured to ensure the proper voltage drops individually across transistors 72 and 74 and proper functioning of main switching transistor 72 in this high voltage domain (e.g., from voltage V_{EX} to voltage V_{SS}).

FIG. 6 shows an illustrative n-type switch formed from a pair of transistors couples in series. In particular, n-type switch 80 may include n-type (n-channel) transistor 82 coupled in series with n-type transistor 84. Transistors 82 and 84 may share a bulk connection to power (voltage) supply rail or terminal 86 supplying the lowest supply voltage level in the pixel (e.g., digital (ground) supply voltage V_{SS}). Transistor 82 may serve as the main switching transistor (sometimes referred to as the switching device). In other words, a control input 83 received at the gate terminal of transistor 82 may determine the state of transistor 82 and therefore the state of n-type switch 80. Transistor 84 may serve as the protection transistor (sometimes referred to as the protection device). Transistor 84 may receive at its gate terminal a bias voltage from bias voltage supply rail or terminal 88 (e.g., different from the bias voltage supplied on terminal 78 in FIG. 5), thereby generating a bias current and corresponding voltage drop across transistor 84. In this manner, transistor 84 is configured to ensure the proper voltage drops individually across transistors 82 and 84 and proper functioning of main switching transistor 82 in this high voltage domain (e.g., from voltage V_{EX} to voltage V_{SS}).

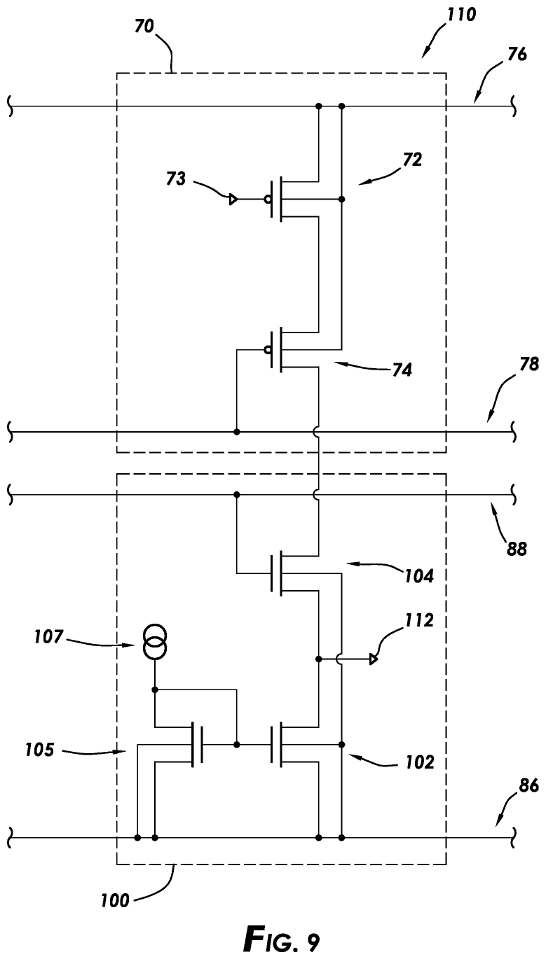

FIG. 7 shows an illustrative current source circuit formed from a stacked-transistor structure. In particular, current source circuit 90 may include p-type transistor 92 coupled in series with p-type transistor 94. Transistors 92 and 94 may share a bulk connection to power (voltage) supply rail or terminal 76 (e.g., the same rail or terminal 76 as in FIG. 5) supplying the highest supply voltage level in the pixel (e.g., excess voltage V_{EX}). Current source circuit 90 may include a current mirror circuit 93 formed from transistor 92, additional p-type transistor 95, and current source 97. As shown in FIG. 7, to form current mirror circuit 93, current source 97 is coupled to the drain terminal of transistor 95, the drain terminal of transistor 95 is connected to the gate terminal of transistor 95 and the gate terminal of transistor 92, and the source and bulk terminals of both transistors 92 and 95 are each connected to voltage supply terminal 76. Configured in this manner, when current source 97 produces current I1, a corresponding current I2 is produced at the drain terminal of transistor 92.

Current mirror circuit 93 may serve as the main current source circuit (sometimes referred to as the main current source device), while transistor 94 may serve as the protection transistor or circuit (sometimes referred to as the protection device). Transistor 94 may receive at its gate terminal a bias voltage from bias voltage supply rail or terminal 78 (e.g., the same rail or terminal 78 as in FIG. 5), thereby generating a bias current and the corresponding voltage drop across transistor 94. In this manner, transistor 94 is configured to ensure the proper voltage drops individually across transistors 92 and 94 and proper functioning of current mirror circuit 93 in this high voltage domain (e.g., from voltage V_{EX} to voltage V_{SS}).

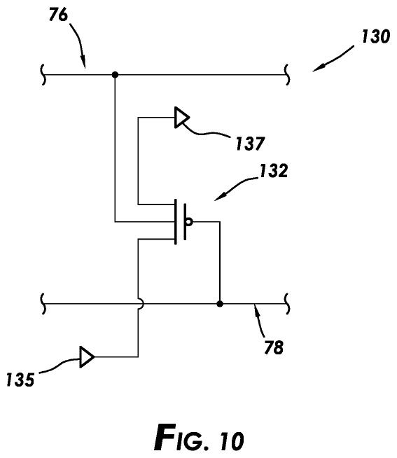

FIG. 8 shows an illustrative current sink circuit formed from a stacked-transistor structure. In particular, current sink circuit 100 may include n-type transistor 102 coupled in series with n-type transistor 104. Transistors 102 and 104 may share a bulk connection to power (voltage) supply rail or terminal 86 (e.g., the same rail or terminal 86 as in FIG. 6) supplying the lowest supply voltage level in the pixel (e.g., ground supply voltage V_{SS}). Current sink circuit 100 may include a current mirror circuit 103 formed from transistor 102, additional n-type transistor 105, and current source 107. As shown in FIG. 8, to form current mirror circuit 103, current source 107 is coupled to the drain terminal of transistor 105, the drain terminal of transistor 105 is connected to the gate terminal of transistor 105 and the gate terminal of transistor 102, and the source and bulk terminals of both transistors 102 and 105 are each connected to voltage supply terminal 86. Configured in this manner, when current source 107 produces current I3, a corresponding current I4 is produced at the drain terminal of transistor 102.

Current mirror circuit 103 may serve as the main current sink circuit (sometimes referred to as the main current sink device), while transistor 104 may serve as the protection transistor or circuit (sometimes referred to as the protection device). Transistor 104 may receive at its gate terminal a bias voltage from bias voltage supply rail or terminal 88 (e.g., the same rail or terminal 88 as in FIG. 6), thereby generating a bias current and the corresponding voltage drop across transistor 104. In this manner, transistor 104 is configured to ensure the proper voltage drops individually across transistors 102 and 104 and proper functioning of current mirror circuit 103 in this high voltage domain (e.g., from voltage V_{EX} to voltage V_{SS}).

Combinations of circuits described above in connection with FIGS. 5-8 may be coupled to one another to form other functional circuits. FIG. 9 shows an illustrative voltage level shifter formed from multiple stacked-transistor structures. As shown in FIG. 9, voltage level shifter 110 may be formed by coupling a p-type switch such as switch 70 in FIG. 5 to a current sink circuit such as current sink circuit 100 in FIG. 8. In particular, transistor 74 in switch 70 has a drain terminal coupled to the drain terminal of transistor 104 in current sink circuit 100. Configured in this manner, an input signal received at input 73 may be level-shifted down to provide an output signal at output 112 coupled the common terminal between transistors 102 and 104 (e.g., the source terminal of transistor 104 and the drain terminal of transistor 102).

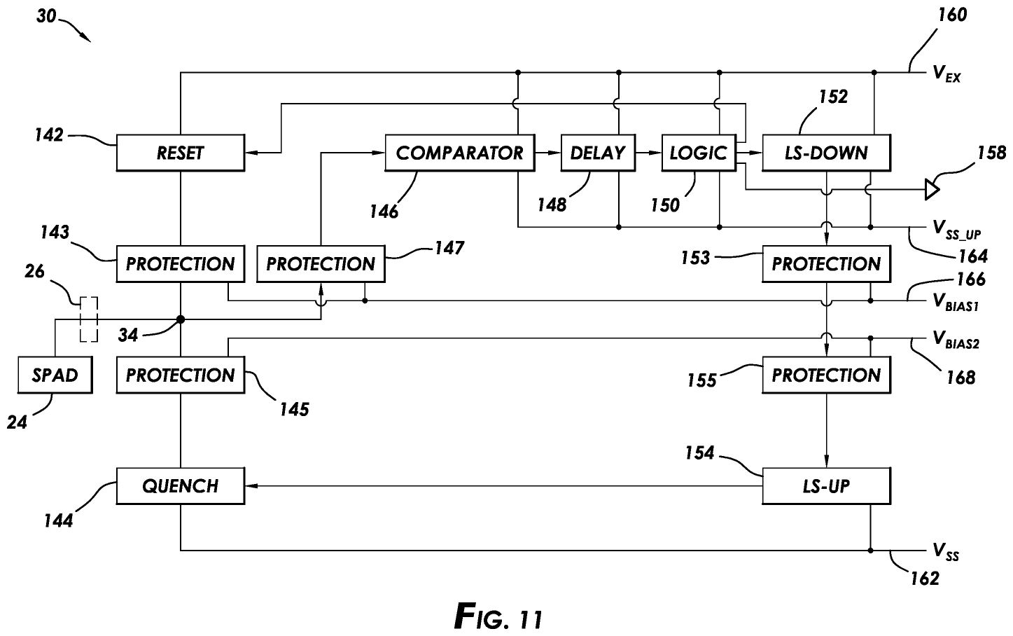

In instances where signals (voltages) in the high voltage domain (e.g., domain containing voltage V_{EX}) are received at circuits in a low voltage domain (e.g., voltage V_{DD} domain excluding voltage V_{EX}), additional protection devices may be provided. As an example, FIG. 10 shows an illustrative protection device for a high voltage input signal from the high voltage domain. As shown in FIG. 10, input 135 may be coupled to the first source-drain terminal (one of a source or drain terminal) of p-type transistor 132, while the second source-drain terminal (the other one of a source or drain terminal) of p-type transistor 132 may be coupled to output 137 (e.g., connected to and supplying an input signal to amplifier circuitry).

Transistor 132 may have a bulk terminal connection to power (voltage) supply rail or terminal 76 (e.g., the same rail or terminal 76 as in FIG. 5) supplying the highest supply voltage level in the pixel (e.g., excess voltage V_{EX}). Transistor 132 may receive at its gate terminal a bias voltage from bias voltage supply rail or terminal 78 (e.g., the same rail or terminal 78 as in FIG. 5), thereby generating a bias current and corresponding voltage drop across transistor 132. In this manner, transistor 84 is configured to ensure the proper voltage drop across transistor 132 and a proper output signal at output 137 to the low voltage domain (e.g., from voltage V_{DD} to voltage V_{SS}).

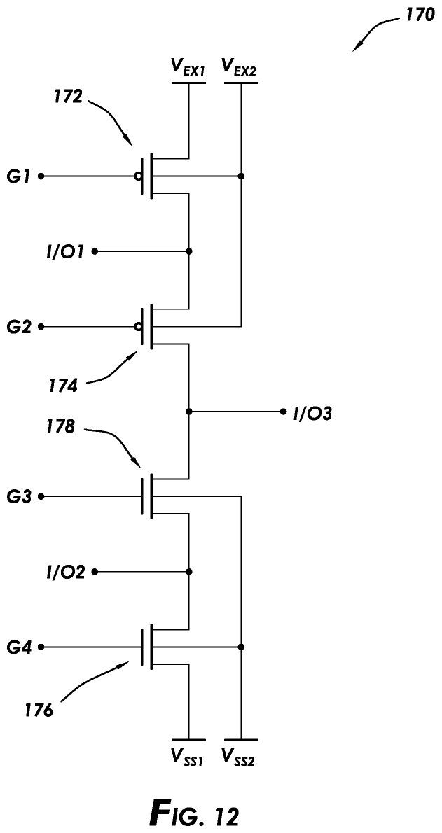

Using the elementary circuits described in connection with FIGS. 5-10 and if desired additional analogous (mirrored) devices based on stacked-transistor devices, pixel 30 may include a number of stacked-transistor devices for supporting a relatively high excess voltage. FIG. 11 is a schematic diagram of how SPAD pixel 30 (FIG. 3) can include stacked-transistor devices for supporting a relatively high excess voltage even when implemented using separated portions in different dies stacked to each other.

As shown in FIG. 11, pixel 30 may include a reset transistor 142 coupled in series with a protection transistor 143 between voltage rail 160 supplying the excess voltage V_{EX} and SPAD cathode terminal 34, thereby implementing reset switch 36 in FIG. 3. Transistors 142 and 143 may be formed using the p-type transistors in the manner shown in FIG. 5 for forming a p-type switch.

Pixel 30 may include a quench transistor 144 coupled in series with a protection transistor 145 between voltage rail 162 supplying the ground voltage V_{SS} and cathode terminal 34, thereby implementing quenching switch 40 in FIG. 3. Transistors 144 and 145 may be formed using the n-type transistors in the manner show in FIG. 6 for forming a n-type switch.

SPAD cathode terminal 34 may be coupled to pixel output terminal 158 (corresponding to output 56 in FIG. 3) via a pixel readout path. In the example of FIG. 11, comparator 146, delay circuit 148, and logic circuit 150 may be coupled along the pixel readout path. While transistors 142, 143, 144, and 145 operate within a high voltage domain (e.g., between voltage V_{EX} and voltage V_{SS}), circuitry coupled along the readout path such as comparator 146, delay circuit 148, and logic circuit 150 may operate within a lower voltage domain (e.g., between voltage V_{EX} and voltage V_{SS}_up, voltage V_{SS}_up being higher than voltage V_{SS}). Accordingly, protection transistor 147 may be coupled along the readout path between cathode 34 and comparator 146. Transistor 132 in FIG. 10 may be used to implement protection transistor 147 with cathode terminal 34 coupled to input 135 (FIG. 10) and comparator circuit 146 coupled to output 136 (FIG. 10).

Signals from the circuitry coupled along the readout path may be used to control reset transistor 142 and quench transistor 144. In the example of FIG. 11, a first output from logic circuit 150 may be used to control reset transistor 142, a second output from logic circuit 150 may be used to control quench transistor 144 (through an intervening level shifting circuit, and a third output from logic circuit 150 may be coupled to pixel output terminal 158.

As shown in FIG. 11, comparator circuit 146, delay circuit 148, and logic circuit 150 are coupled between voltage rail 160 supplying excess voltage V_{EX} and voltage rail 164 supplying an elevated (relative ground) voltage V_{SS_UP} and therefore operate between these two voltages. As such when controlling transistor 144 operating at a lower voltage, the third output signal from logic circuit 150 should be (voltage) level-shifted down before being used to control quench transistor 144. This may be achieved using transistors 152, 153, 154, and 155. Transistors 152, 153, 154, and 155 may be configured in the same manner as transistors 72, 74, 102, and 104 as shown in FIG. 9 for forming a level shifting circuit (e.g., with the inclusion of additional elements such as current source 107, transistor 105, etc., as shown in FIG. 9 but excluded from FIG. 11 in order to not obscure the embodiments). If desired, the output 158 may also be coupled to a (voltage) level shifting circuit to shift the pixel output signal down.

In pixel 30, p-type protection transistors such as transistors 143, 147, and 153 may each have a gate terminal coupled to voltage rail 166 supplying a first bias voltage V_{BIAS1}. Analogously, in pixel 30, n-type protection transistors such as transistors 145 and 155 may each have a gate terminal coupled to voltage rail 168 supplying a second bias voltage V_{BIAS2}.

While not explicitly shown in FIG. 11, p-type transistors in the high voltage domain (e.g., operating between voltages V_{EX} and V_{SS}) such as transistors 142, 143, 147, 152, and 153 may each have a bulk terminal provided with a common bulk voltage, which may be the highest voltage in the high voltage domain (e.g., voltage V_{EX}). Analogously, n-type transistors in the high voltage domain (e.g., operating between voltages V_{EX} and V_{SS}) such as transistors 144, 145, 154, and 155 may each have a bulk terminal provided with a common bulk voltage, which may be the lowest voltage in the high voltage domain (e.g., voltage V_{SS}).

Configured in this manner, pixel 30 may provide a SPAD cathode terminal 34 configured to receive voltage V_{EX} (higher than the normal digital circuitry voltage V_{DD}, which may be the voltage difference between V_{EX} and V_{SS} up) through transistors 142 and 143. Protection circuits (transistors) may insulate the readout circuitry operating at a lower voltage domain from the SPAD cathode terminal 34 configured to receive voltages from the high voltage domain (e.g., voltage V_{EX}). Level shifters with stacked transistor devices may be used to level-shift signals as desired between the two voltage domains.

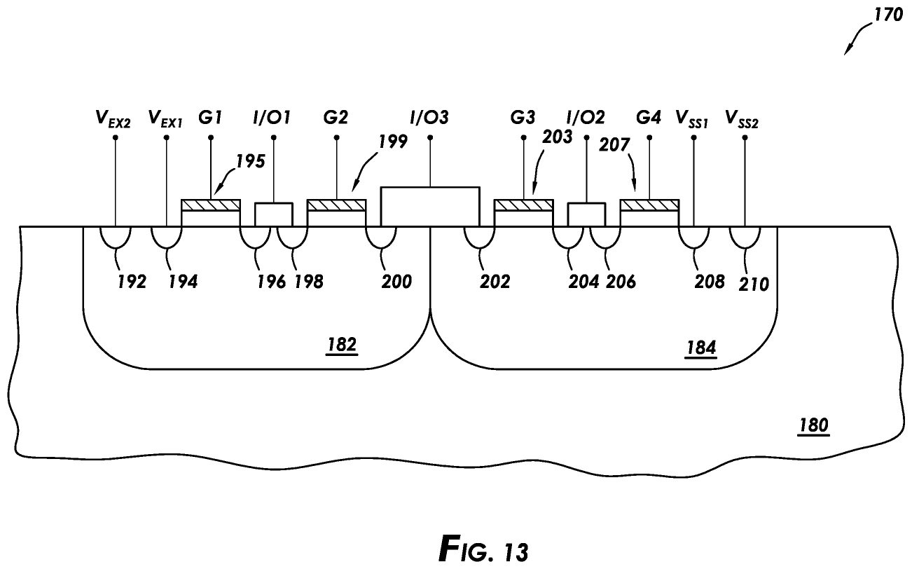

To further compact the pixel configuration when using stacked-transistor devices as described in connection with FIGS. 3-11, these stacked-transistor devices may be formed within shared doped (e.g., n-type material doped or p-type material doped) wells. As an example, FIG. 12 shows an illustrative SPAD pixel portion 170 containing two p-type transistors and two n-type transistors (e.g., forming some portion of pixel 30 in FIG. 11 such as transistors 142, 143, 144, and 145, transistors 152, 153, 154, and 155, or other sets of transistors in a SPAD pixel).

In the example of FIG. 12, p-type transistor 172 may have a source terminal coupled to a voltage terminal supplying voltage V_{EX1}, a bulk terminal coupled to a voltage terminal supplying voltage V_{EX2}, a drain terminal coupled to transistor 174, and a gate terminal coupled to a control input G1. P-type transistor 174 may have a source terminal coupled to transistor 172, a bulk terminal coupled to the voltage terminal supplying voltage supplying voltage V_{EX2}, a drain terminal coupled to transistor 178, and a gate terminal coupled to a control input G2. The shared terminal between transistors 172 and 174 may, if desired, be an input or output terminal and therefore be coupled to an input-output line I/O1.

In the example of FIG. 12, n-type transistor 176 may have a source terminal coupled to a voltage terminal supplying voltage V_{SS1}, a bulk terminal coupled to a voltage terminal supplying voltage V_{SS2}, a drain terminal coupled to transistor 178, and a gate terminal coupled to a control input G4. N-type transistor 178 may have a source terminal coupled to transistor 176, a bulk terminal coupled to the voltage terminal supplying voltage supplying voltage V_{SS2}, a drain terminal coupled to transistor 174, and a gate terminal coupled to a control input G3. The shared terminal between transistors 176 and 178 may, if desired, be an input or output terminal and therefore be coupled to an input-output line I/O2. The shared terminal between transistors 174 and 178 may, if desired, be an input or output terminal and therefore by coupled to an input-output line I/O3.

FIG. 13 is a cross-sectional view of a substrate in which SPAD pixel portion 170 may be formed. In particular, as described in connection with FIGS. 2 and 3, the SPAD pixel may be split between sensor die 22 and readout die 28. The SPAD in the pixel may be formed in sensor die 22 and the remaining circuits in the pixel may be formed in readout die 28. Accordingly, in the example of FIG. 13, substrate 180 in which pixel portion 170 is formed may be the semiconductor (e.g., silicon) substrate for readout die 28.

Substrate 180 may be a substrate of a first doping-type such as p-type (e.g., a semiconductor substrate lightly-doped with p-type material such as boron, aluminum, gallium, etc.). Wells 182 and 184 of opposite doping types formed within substrate 180. As an example, well 182 may be an n-type well (e.g., lightly-doped with excess n-type carriers, e.g., using n-type materials such as phosphorus, arsenic, antimony, etc.) and well 184 may be a p-type well (e.g., light-doped with excess p-type carriers). Configured in this manner, n-type well 182 may form the shared bulk terminal for p-type stacked-transistor devices in the SPAD pixel and p-type well 184 may form the shared bulk terminal for n-type stacked-transistor devices in the SPAD pixel.

To achieve a shared bulk connection, a heavily-doped n-type contact region 192 may be provided in n-type well 182 and may be supplied with voltage V_{EX2} (the desired shared bulk voltage) using a voltage supply terminal or rail. Analogously, a heavily-doped p-type contact region 210 may be provided in p-type well 184 and may be supplied with voltage V_{SS2} (the desired shared bulk voltage) using a voltage supply terminal or rail.

In general, all stacked-transistor devices in the SPAD pixel may desirably be formed either in n-type well 182 (if the device is p-type) and in p-type well 184 (if the device is n-type). In such a manner, only two wells are needed to form the numerous stacked-transistor devices in each SPAD pixel, thereby compacting SPAD pixel layout.

As examples, p-type transistor 172 having a heavily-doped p-type source terminal contact 194, a heavily-doped p-type drain terminal contact 196, and gate structures 195 (e.g., a gate conductor and a gate insulator separating the gate conductor from the channel region) may be formed at n-type well 182. P-type transistor 174 having a heavily-doped p-type source terminal contact 198, a heavily-doped p-type drain terminal contact 200, and gate structures 199 (e.g., a gate conductor and a gate insulator separating the gate conductor from the channel region) may be formed at n-type well 182. N-type transistor 178 having a heavily-doped n-type drain terminal contact 202, a heavily-doped n-type source terminal contact 204, and gate structures 203 (e.g., a gate conductor and a gate insulator separating the gate conductor from the channel region) may be formed at well 184. N-type transistor 176 having a heavily-doped n-type drain terminal contact 206, a heavily-doped n-type source terminal contact 208, and gate structures 207 (e.g., a gate conductor and a gate insulator separating the gate conductor from the channel region) may be formed at well 184.

These examples using pixel portion 170 in FIGS. 12 and 13 are merely illustrative. Pixel transistor structures outside of pixel portion 170 may also be formed at either well 182 or well 184. If desired, supply voltages and/or input-output terminals for pixel portion 170 may be changed and/or omitted as desired for the pixel design. While voltages V_{EX1} and V_{EX2} are shown separately, they may be the same voltage (or if desired, different voltages). Similarly, while voltages V_{SS1} and V_{SS2} are shown separately, they may be the same voltage (or if desired, different voltages).

While FIGS. 12 and 13 are described in the context of a p-type substrate, this is merely illustrative. If desired, the doping types of substrates, wells, contacts, etc. may be switched accordingly to implement the same type of circuits in differently-doped substrates.

In any of the aforementioned embodiments, it should be understood that a silicon photomultiplier (with multiple SPAD pixels having a common output) may be used in place of a single SPAD pixel. In other words, portions of readout circuits on readout die 28 may be shared by and coupled to a plurality of SPAD pixels on sensor die 22 instead of a single SPAD pixel on sensor die 22.

If desired, with the existence of multiple voltage domains in each pixel 30, the test input supplied to control circuit 40 (FIG. 3) may include one or more test signals for testing components in the higher voltage domain and may include one or more test signals for testing components in the lower voltage domain.

In various embodiments described herein, SPAD pixels each having stacked-transistor devices (e.g., protection devices) that enable the supplying of a relatively high excess voltage level to SPAD cathodes are provided.

As an example, a semiconductor device may include a first integrated circuit die, a single-photon avalanche diode in the first integrated circuit die, a second integrated circuit die mounted to the first integrated circuit die, and a stacked-transistor structure in the second integrated circuit die coupling a voltage supply terminal to a cathode terminal of the single-photon avalanche diode. The stacked-transistor structure may include first and second transistors coupled in series between the voltage supply terminal and the cathode terminal of the single-photon avalanche diode and having a shared bulk connection to the voltage supply terminal.

If desired, the stacked-transistor structure may form a reset switch for the single-photon avalanche diode and the voltage supply terminal may be configured to supply an excess voltage that, when applied to the cathode terminal, configures the single-photon avalanche diode for a detection operation. If desired, the stacked-transistor structure may form a quenching switch (e.g., forming a portion of an active quenching circuit) for the single-photon avalanche diode and the voltage supply terminal may be configured to supply a ground voltage.

Readout circuitry (e.g., a comparator circuit, a delay circuit, a logic circuit, etc.) along a readout path may couple the cathode terminal of the single-photon avalanche diode to a pixel output terminal. A delay circuit along the readout path may provide an output that is coupled (e.g., through an intervening logic circuit) to a quenching switch via a voltage level shifter that comprises the stacked transistor structure.

As another example, a semiconductor device may include a semiconductor substrate, a first well of a first doping type for a single-photon avalanche diode pixel formed in the semiconductor substrate, a second well of a second doping type for the single-photon avalanche diode pixel formed in the semiconductor substrate, a first plurality of transistors for the single-photon avalanche diode pixel having a shared bulk terminal formed at the first well, and a second plurality of transistors for the single-photon avalanche diode pixel having a shared bulk terminal formed at the second well.

In this example, if desired, the shared bulk terminal of the first plurality of transistors may be connected to a first voltage terminal supplying a first voltage, and the shared bulk terminal of the second plurality of transistors may be connected to a second voltage terminal supplying a second voltage. The semiconductor device may further include readout circuitry for the single-photon avalanche diode pixel formed on the semiconductor substrate. The readout circuitry may be configured to operate in a low voltage domain, and the first and second pluralities of transistors may be configured to operate in a high voltage domain.

In this example, if desired, the first plurality of transistors may include two series-connected transistors that form a reset switch for the single-photon avalanche diode pixel, and the second plurality of transistors may include two series-connected transistors that form a quenching switch for the single-photon avalanche diode pixel.

The foregoing is merely illustrative of the principles of this invention and various modifications can be made by those skilled in the art. The foregoing embodiments may be implemented individually or in any combination.

What is claimed is:

1. A semiconductor device comprising:
a first integrated circuit die;
a single-photon avalanche diode in the first integrated circuit die;
a second integrated circuit die mounted to the first integrated circuit die; and
a stacked-transistor structure in the second integrated circuit die coupling a voltage supply terminal to the single-photon avalanche diode.

2. The semiconductor device defined in claim 1, wherein the stacked-transistor structure comprises first and second transistors coupled in series between the voltage supply terminal and a cathode terminal of the single-photon avalanche diode.

3. The semiconductor device defined in claim 2, wherein the first transistor has a bulk terminal, the second transistor has a bulk terminal, and the bulk terminal of the first transistor is coupled to the bulk terminal of the second transistor and the voltage supply terminal.

4. The semiconductor device defined in claim 2, wherein the first transistor is a reset transistor for the single-photon avalanche diode and the voltage supply terminal is configured to supply an excess voltage that, when applied to the cathode terminal, configures the single-photon avalanche diode for a detection operation.

5. The semiconductor device defined in claim 4, wherein the second transistor is disposed between the first transistor and the cathode terminal.

6. The semiconductor device defined in claim 5, wherein the first and second transistors are p-type transistors

7. The semiconductor device defined in claim 2, wherein the first transistor forms an active quenching circuit for the single-photon avalanche diode and the voltage supply terminal is configured to supply a ground voltage.

8. The semiconductor device defined in claim 7, wherein the second transistor is disposed between the first transistor and the cathode terminal.

9. The semiconductor device defined in claim 8, wherein the first and second transistors are n-type transistors.

10. The semiconductor device defined in claim 1 further comprising:
an additional stacked-transistor structure in the second integrated circuit die coupling an additional voltage supply terminal to the single-photon avalanche diode; and
a readout path, wherein the single-photon avalanche diode, the stacked-transistor structure, the additional stacked transistor structure, and the readout path forms a pixel, and the readout path couples the single-photon avalanche diode to a pixel output terminal.

11. A single-photon avalanche diode pixel comprising:
a diode having an anode terminal and a cathode terminal;
a reset switch coupling the cathode terminal of the diode to a first voltage terminal;
a quenching switch coupling the cathode terminal of the diode to a second voltage terminal; and
readout circuitry along a readout path coupling the cathode terminal of the diode to a pixel output terminal, wherein at least one of the reset switch, the quenching switch, or the readout circuitry comprises two series-connected transistors having a shared bulk terminal.

12. The single-photon avalanche diode pixel defined in claim 11, wherein the readout circuitry comprises a delay circuit, and an output of the delay circuit is coupled to the quenching switch via a voltage level shifter that comprises the two series-connected transistors having the shared bulk terminal.

13. The single-photon avalanche diode pixel defined in claim 11, wherein the reset switch comprises the two series-connected transistors having the shared bulk terminal, and the shared bulk terminal is coupled to the first voltage terminal.

14. The single-photon avalanche diode pixel defined in claim 11, wherein the quenching switch comprises the two series-connected transistors having the shared bulk terminal, and the shared bulk terminal is coupled to the second voltage terminal.

15. The single-photon avalanche diode pixel defined in claim 11, wherein the diode is on a first integrated circuit die, and the reset switch, the quenching switch, and the readout circuitry are on a second integrated circuit die mounted to the first integrated circuit die.

16. A semiconductor device comprising:
a semiconductor substrate;
a first well of a first doping type for a single-photon avalanche diode pixel formed in the semiconductor substrate;
a second well of a second doping type for the single-photon avalanche diode pixel formed in the semiconductor substrate;
a first plurality of transistors for the single-photon avalanche diode pixel having a shared bulk terminal formed at the first well; and
a second plurality of transistors for the single-photon avalanche diode pixel having a shared bulk terminal formed at the second well.

17. The semiconductor device defined in claim 16, wherein the shared bulk terminal of the first plurality of transistors is connected to a first voltage terminal supplying a first voltage, and the shared bulk terminal of the second plurality of transistors is connected to a second voltage terminal supplying a second voltage.

18. The semiconductor device defined in claim 17 further comprising:
readout circuitry for the single-photon avalanche diode pixel formed on the semiconductor substrate, wherein the readout circuitry is configured to operate in a low voltage domain, and the first and second pluralities of transistors are configured to operate in a high voltage domain.

19. The semiconductor device defined in claim 16, wherein the first plurality of transistors includes two series-connected transistors that form a reset switch for the single-photon avalanche diode pixel.

20. The semiconductor device defined in claim 19, wherein the second plurality of transistors includes two series-connected transistors that form a quenching switch for the single-photon avalanche diode pixel.
